(19) United States
(12) Patent Application Publication
(10) Pub. No.: US 2008/0315183 A1
(43) Pub. Date: Dec. 25, 2008

(54) SEMICONDUCTOR DEVICE WITH CARBON NANOTUBE CHANNEL AND MANUFACTURING METHOD THEREOF

(76) Inventors: Atsuhiro KINOSHITA, Kanagawa (JP); Yoshifumi Nishi, Kanagawa (JP); Ken Uchida, Tokyo (JP); Junji Koga, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/052,229

(22) Filed: Mar. 20, 2008

(30) Foreign Application Priority Data
Mar. 23, 2007 (JP) 2007-076169

(51) Int. Cl. H01L 29/12; H01L 21/336

(52) U.S. Cl. 257/24; 438/151; 257/E29.07; 257/E21.409

(57) ABSTRACT

A high-performance semiconductor device having a channel region structured from a carbon nanotube (CNT) for reducing or minimizing a drain leakage current is provided. This semiconductor device includes, in addition to the CNT-formed channel region, a gate electrode formed to overlie the channel region with a gate insulation film sandwiched therebetween, and a pair of source and drain regions interposing the channel region therebetween. The source and drain regions have portions in contact with the channel region, which portions are made of a specific semiconductor material that is wider in energy band gap than the channel region.

### CROSS-REFERENCE TO RELATED APPLICATION

This application is based upon and claims the benefit of priority from Japanese Patent Application No. 2007-76169, filed on Mar. 23, 2007, the entire contents of which are incorporated herein by reference.

### FIELD OF THE INVENTION

The present invention relates to a semiconductor device of the type having a channel region formed of a carbon nanotube, and also relates to a method of manufacturing the semiconductor device. More particularly but not exclusively, this invention relates to a highly miniaturized carbon nanotube transistor structure and a manufacturing method of the same.

### BACKGROUND OF THE INVENTION

Silicon large-scale integrated (LSI) circuit technology is one of the infrastructure technologies which support advancement of the information society in future. For further improvement of the functionalities of LSI circuits, a need is felt to enhance the performance of metal insulator semiconductor (MIS) field effect transistors, which are constituent elements of LSI chips. Until today, the device performance enhancement has been done principally based on proportional shrinking or “scaling” rules. In recent years, this approach is encountered, due to the presence of various physical limits, with difficulties not only in achievement of higher performances by device microfabrication but also in retention of proper operations of the devices per se. To break through such difficulties, attempts are made by semiconductor manufacturers in the world to realize high-performance transistors by formation of a channel region using a new material alternative to the silicon.

One example of the attempts is an approach for forming the channel region of a p-type field effect transistor by germanium (Ge). Another example is to form the channel region of an n-type field effect transistor by use of a compound semiconductor, such as gallium arsenide (GaAs) or indium phosphide (InP) or the like. A further example is to form the channel region by a carbon nanotube (CNT). A transistor having such carbon nanotube channel region is called the carbon nanotube transistor. Of these approaches, the method of forming the channel region by the carbon nanotube is taken a hopeful view because of its advantages as to the achievability of a field effect transistor with an ultra-small gate length while reducing complexities and also the ability to form channel regions of both n-type and p-type field effect transistors by use of a single kind of material. As a consequence, vigorous studies are being made of specific types of transistors, including a Schottky transistor having a channel region formed of a carbon nanotube and using a Schottky junction between a metal and the carbon nanotube (semiconductor) as the source/drain junction thereof, and a transistor having an n-type layer formed by doping of kalium and a p-n junction for use as its source/drain junction.

In addition, a carbon nanotube transistor suitable for mass-production is also proposed, an example of which is disclosed, for example, in JP-A 2004-165297 (KOKAI). Typically, carbon nanotubes are relatively narrow in energy band gap among currently available semiconductor materials, the value of which is 0.6 eV or more or less. Accordingly, in Schottky transistors of the type having a channel region formed of a carbon nanotube and using a junction between a metal and the carbon nanotube (semiconductor) as the source/drain junction, there was a problem as to an unwanted increase in drain leakage current due to the tunneling of carriers from the drain side to the channel region side. More specifically, in the Schottky transistors, a metal becomes the supply source of both electrons and holes. Thus, in an n-channel type transistor, holes behave to tunnel from the drain side to the channel due to a decreased height of Schottky barrier; in a p-channel type transistor, electrons tunnel from the drain side to the channel for the same reason.

Alternatively, in the case of a carbon nanotube transistor with p-n junctions as the source and drain junctions, the tunneling of Schottky barrier from the drain no longer takes place unlike the case of Schottky transistors. However, in case the transistor has a highly miniaturized channel, a problem occurs as to an increase in drain leakage current due to direct band tunneling.

### SUMMARY OF THE INVENTION

A semiconductor device in accordance with a first form of the present invention includes a channel region which is formed of a carbon nanotube (CNT), a gate dielectric film on the channel region, a gate electrode on the gate dielectric film, and a pair of source and drain regions interposing the channel region therebetween, wherein portions of the source and drain regions which are in contact with the channel region are made of a semiconductive material that is wider in band gap than the channel region.

A manufacturing method of the semiconductor device in accordance with the first form of this invention includes the steps of forming a dielectric layer on a semiconductor substrate, forming on the dielectric layer a carbon nanotube for use as a channel region, forming a gate insulation film on the carbon nanotube, forming a gate electrode on the gate insulation film, forming a sidewall insulator film on laterally opposite sides of the gate electrode, etching the dielectric layer with the gate electrode and the sidewall insulator film being as a mask to thereby partially expose the semiconductor substrate, forming by epitaxial growth a semiconductor layer on the semiconductor substrate to thereby cause the semiconductor layer to come into contact with the carbon nanotube, which layer becomes part of a source region and a drain region.

A semiconductor device manufacturing method in accordance with a second form of the invention includes forming a dielectric layer on a semiconductor substrate, forming on the dielectric layer a carbon nanotube for use as a channel region, forming a gate insulation film on the carbon nanotube, forming a gate electrode on the gate insulation film, forming a sidewall insulator film on both sides of the gate electrode, and changing by substitution or replacement the carbon nanotube to a boron nitride nanotube with the gate electrode and the sidewall insulator film being used as a mask.

### BRIEF DESCRIPTION OF THE DRAWINGS

FIGS. 1A to 1C are diagrams each illustrating, in cross-section, the structure of a semiconductor device in accordance with a first embodiment of this invention.

FIGS. 2A-2C are energy band diagrams for explanation of functions and effects of the first embodiment.

FIGS. 3A through 7D are plan views and sectional views for explanation of a fabrication method of the semiconductor device shown in FIGS. 1A-1C .

FIGS. 8A-8C are diagrams showing the structure of a semiconductor device of a second embodiment of the invention.

FIGS. 9A-9C are diagrams showing a semiconductor device structure of third embodiment.

FIGS. 10A-10C are diagrams showing a semiconductor device structure of fourth embodiment.

FIGS. 11A to 13D are plan views and sectional views for explanation of a fabrication method of the semiconductor device of FIGS. 10A-10C.

FIGS. 14A-14C are diagrams showing a semiconductor device structure of fifth embodiment.

FIGS. 15A-15C are diagrams showing a semiconductor device structure of sixth embodiment.

FIGS. 16A-16C are diagrams showing a semiconductor device structure of seventh embodiment.

### DETAILED DESCRIPTION OF THE EMBODIMENTS

Currently preferred forms of the present invention will be described with reference to the accompanying figures of the drawing below.

### First Embodiment

A semiconductor device in accordance with first embodiment of this invention is a semiconductor device having an n-type field effect transistor with electrons as its carriers. This device has a channel region of the field effect transistor which channel is formed of a carbon nanotube (CNT), a gate electrode that is formed above this channel region with a dielectric film being sandwiched between them, and a couple of source and drain regions which are formed with the channel region being laterally interposed therebetween. The device is arranged so that a portion of each of the source and drain regions which is in contact with the channel region is made of a specifically chosen semiconductor material that is wider in band gap than the channel region.

The semiconductor device of this embodiment is that the semiconductor material of the portions of the source and drain regions which are in contact with the channel region is made for example of silicon (Si), which is higher in state density than the carbon nanotube of channel part and which is wide in band gap. The band gap of the carbon nanotube is at about 0.6 eV when its diameter is approximately 1 nm, although the carbon nanotube band gap exhibits diameter dependency. In contrast, the band gap of silicon is about 1.12 eV, which is greater than that of the former. In this way, by the use of such band gap-widened material which is higher in state density than the carbon nanotube, it becomes possible to suppress drain leakage current even when letting the carbon nanotube be the channel region.

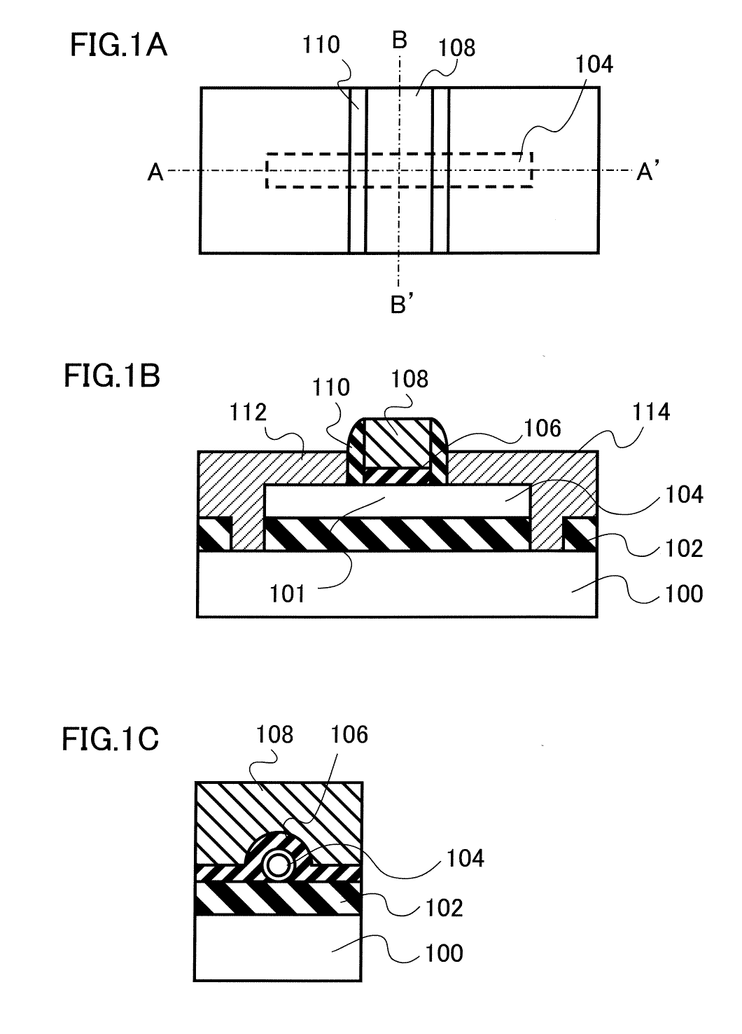

FIGS. 1A to 1C are diagrams each showing a device structure of the semiconductor device of this embodiment. FIG. 1A is a plan view, FIG. 1B is a cross-sectional view as taken along line A-A′ of FIG. 1A, and FIG. 1C is a sectional view taken along line B-B′ of FIG. 1A.

Firstly, as shown in FIGS. 1A-1C , the semiconductor device of this embodiment is a field effect transistor having a channel region 101 which is formed of a carbon nanotube (CNT) 104. This carbon nanotube 104 is a carbon nanotube having characteristics of a semiconductor body with its diameter of 1.5 nm, as an example. As shown in FIG. 1B, it has above the channel region 101 a gate electrode 108 which was formed on a gate insulating film 106 made of HfO₂, for example. This gate electrode 108 may be made of a metal silicide, such as for example nickel silicide (NiSi) or the like. Note here that as shown in FIG. 1C, the gate insulator film 106 and the gate electrode 108 are formed to surround the carbon nanotube 104 of channel region 101. As shown in FIG. 1B, a sidewall insulator film 110 is formed on laterally opposite sidefaces of the gate electrode. An example of the film is a silicon nitride (SiN) film.

Furthermore, a source region 112 and a drain region 114, which are made of silicon with an n-type impurity, such as arsenic (As) for example, being doped therein to have the n-type conductivity, are formed so that the channel region 101 is laterally interposed between these source and drain regions. Accordingly, portions of the source region 112 and drain region 114 which are in contact with the channel region 101—i.e., portions of the source region 112 and drain region 114 in vicinity to the sidewall dielectric film 110—are structured so that each is made of single-crystalline or “monocrystalline” silicon, which is a semiconductor material that is wider in band gap than the channel region 101.

Here, the carbon nanotube 104 that constitutes the channel region 101 are formed on an electrically insulative layer 102 that was formed on a semiconductor substrate 100 as shown in FIGS. 1B and 1C. The semiconductor substrate 100 is made of single-crystal silicon whereas the dielectric film 102 is a silicon oxide film, for example.

According to the illustrative embodiment, it becomes possible to suppress any possible flow of drain a leakage current of the carbon nanotube transistor while at the same time enabling this transistor to increase in magnitude of a turn-on current thereof. An explanation will be given of functions and effects obtainable by this embodiment with reference to some of the accompanying drawings below.

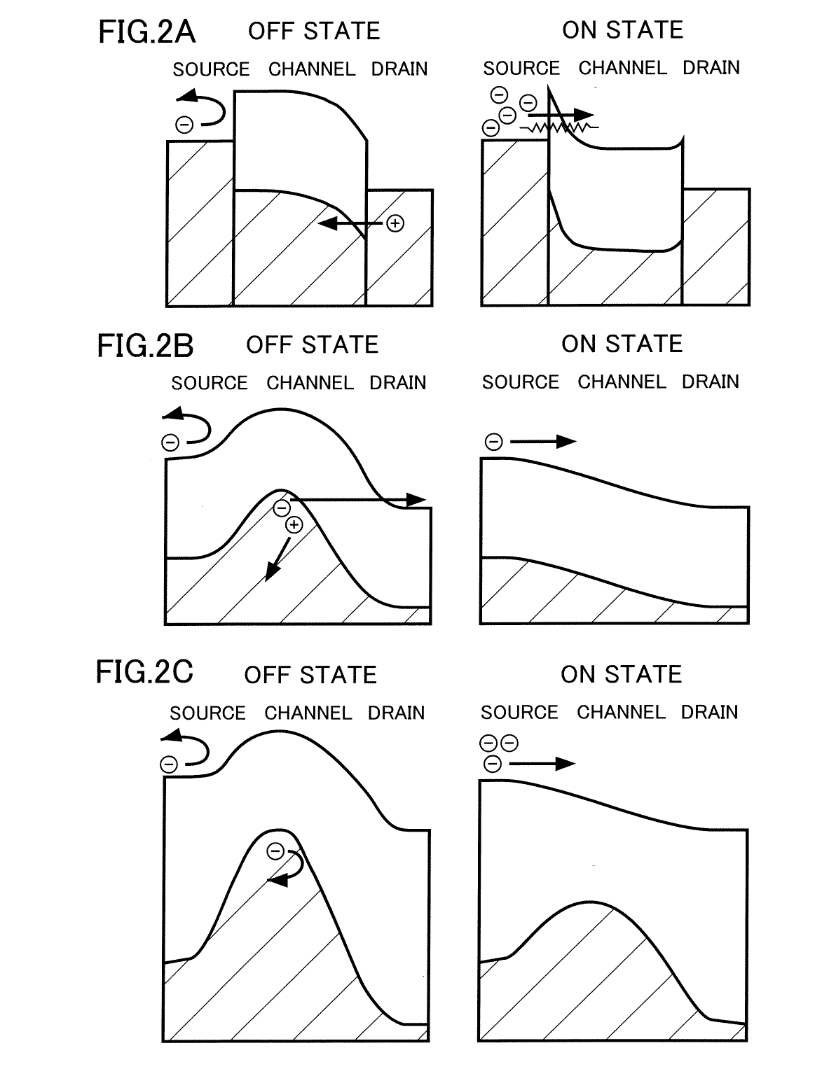

FIGS. 2A to 2C are energy band diagrams for explanation of the functions and effects of this embodiment. FIGS. 2A, 2B and 2C are the drawings in the case of source and drain regions having Schottky junction, in the case of source and drain regions each of which is formed of an impurity-doped carbon nanotube, and in the case of the source and drain regions of this embodiment, respectively. Additionally, FIGS. 2A-2C assume the case of an n-type field effect transistor.

In the case of the Schottky junction shown in FIG. 2A, the channel region of carbon nanotube is in contact with the source and drain regions made of a metal. The metal acts as a supply source of both electrons and holes. Thus, in the case of a turn-off state shown in the left-hand side drawing, holes can exhibit tunneling from the drain side, resulting in unwanted generation of a large drain leakage current. This becomes a problem. On the other hand, the metal is larger in state density than the carbon nanotube. Thus, in the case of a turn-on state shown in the right-hand side part of FIG. 2A, it is possible to inject an increased number of carriers—here, electrons—into the channel region. This makes it expectable to increase the turn-on current. Unfortunately, this advantage does not come without accompanying a penalty which follows: parasitic resistance due to the presence of Schottky barrier on the source side restricts the turn-on current in case the transistor is miniaturized or downscaled.

Next, in the case of FIG. 2B, the channel region of carbon nanotube is contacted with its associated source and drain regions by p-n junction of carbon nanotube. In the case of an off state of the left-side part of FIG. 2B, miniaturization of the channel region poses a problem which follows: electrons or holes behave to directly tunnel between energy bands in the drain region due to the fact that the carbon nanotube is narrow in band gap, resulting in unwanted production of drain leakage current. Alternatively, in the case of an on state shown in the right side drawing, the above-stated Schottky barrier-cased parasitic resistance problem does not take place. However, the carrier amount is less because of the insignificance of the state density of carbon nanotube. This makes it unexpectable to achieve any large turn-on current.

On the contrary, in the case of the embodiment shown in FIG. 2C, source/drain region is formed of a specific semiconductor body which is wider in band gap than the carbon nanotube and which is large in state density—for example, silicon. Accordingly, in the off state shown in the left side part of FIG. 2C, it is difficult for electrons or holes to perform tunneling in the drain region, which in turn makes it possible to suppress the drain leakage current in the off state. In addition, in the on state of the right side drawing, it becomes possible to flow a large amount of drain current. One reason of it is that there is no Schottky barrier-caused parasitic resistance. Another reason is that the carrier amount stays larger because the state density is large.

In this embodiment, the diameter of the carbon nanotube of the channel region is preferably set to fall within a range of 1 nm to 3 nm; more preferably, it ranges from 1.5 to 3 nm, although these values are not to be construed as limiting the invention. The reason of this value setting is as follows. The band gap of the carbon nanotube depends on the diameter of carbon nanotube as stated previously. When the diameter becomes less than the value of 1.5 nm, the band gap expands, causing the turn-on current to decrease. This current decrease is also due to the lowness of the state density. If the carbon nanotube diameter goes below 1 nm, the on current decrease becomes more appreciable, posing a problem as to a decrease in transistor driving ability or “drivability.” Alternatively, when the carbon nanotube diameter goes beyond 3 nm, the carbon nanotube becomes smaller in band gap. This can sometimes pose a problem as to a decrease in functionality of the carbon nanotube as a semiconductor body at room temperatures. Although in FIGS. 1A-1C there is shown the case where a single carbon nanotube is employed, it is also permissible, when the need arises, to use a parallel layout of more than two carbon nanotubes in order to increase the on current.

While the case where the semiconductor material of the portions of source and drain regions in contact with the channel region is silicon was explained here as an example, this material is not to be construed as limiting the invention and may be replaced by any other similar suitable semiconductive materials which are wider in band gap than the carbon nanotube of the channel region. Examples of such materials are germanium (Ge) and silicon germanium (SiₓGe₁₋ₓ), which are IV-group crystals. Other examples are gallium arsenide (GaAs), indium nitride (InN), aluminum nitride (AlN), which are III-V group crystals.

Also note that although the explanation above was given by taking the n-type field effect transistor as an example, similar results are obtainable when replacing it by a p-type field effect transistor: a mere difference between them is that the carriers for the latter are holes rather than electrons in the former. Regarding the semiconductor substrate 100, dielectric layer 102, gate insulator film 106, gate electrode 108 and gate sidewall dielectric film 110 shown in FIGS. 1A-1C also, these should not be limited to the above-noted materials and may be made of other similar suitable known materials on a case-by-case basis.

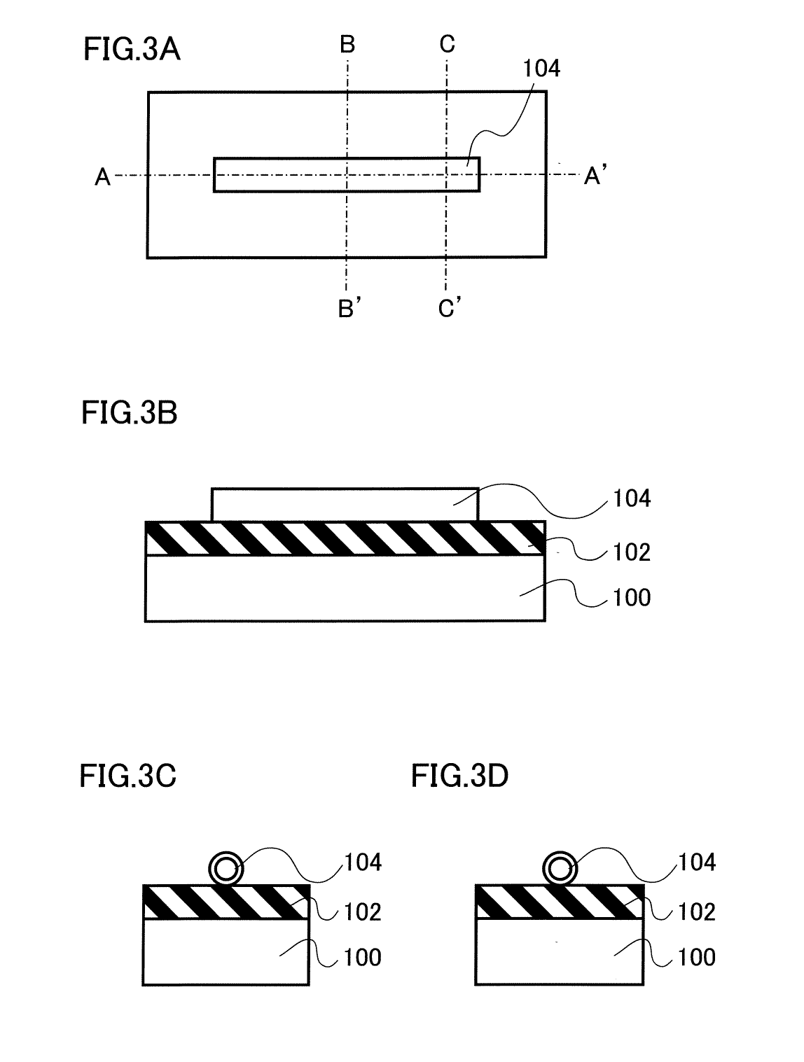

An explanation will next be given of a fabrication method of the semiconductor device of this embodiment shown in FIGS. 1A-1C while referring to FIGS. 3A through 7D below. First, as shown in a plan view of FIG. 3A, FIG. 3B which is a cross-sectional view as taken along line A-A′ of FIG. 3A, FIG. 3C which is a sectional view taken along line B-B′ of FIG. 3A, and FIG. 3D that is a sectional view along line C-C′ of FIG. 3A, a dielectric film 102 which is made for example of silicon oxide is formed on semiconductor substrate 100 made of silicon. Then, a carbon nanotube 104 which becomes the channel region of a field effect transistor is formed on the dielectric film 102.

Here, the carbon nanotube 104 is formed by any one of known techniques, such as chemical vapor deposition (CVD), arc discharging, laser abrasion and others. By arbitrarily changing process conditions such as temperature, pressure and time in the growth process, it is possible to form it to have a desired diameter, length and electrical characteristics. As the carbon nanotube of semiconductor has the nature of a p-type semiconductor in most cases, it is also possible to use the embodiment which forms an n-type field effect transistor without having to perform any particular doping. Additionally, in the case of the p-type field effect transistor being formed, this transistor is also convertable to n-type semiconductor by ion injection or implantation of a chosen element, such as kalium (K) or else, by way of example.

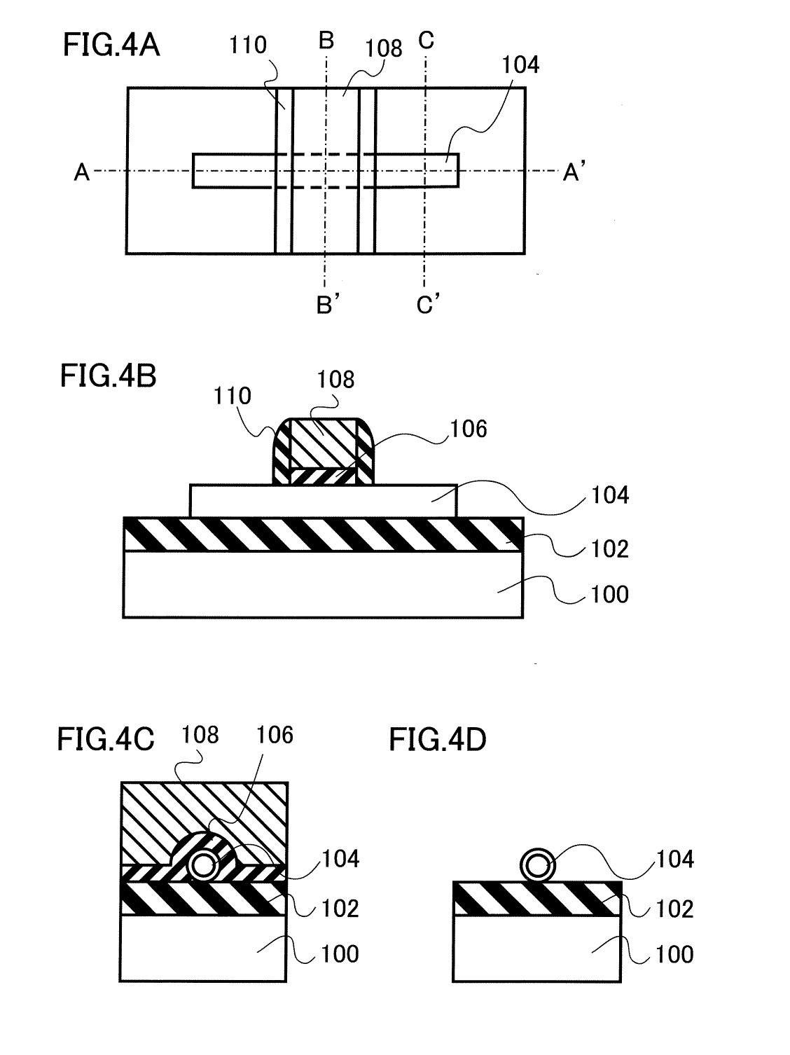

Next, as shown in a plan view of FIG. 4A, FIG. 4B which is a sectional view as taken along line A-A′ of FIG. 4A, FIG. 4C which is a sectional view taken along line B-B′ of FIG. 4A, and FIG. 4D that is a sectional view a-long line C-C′ of FIG. 4A, a gate insulator film 106 made for example of HfO₂ is formed on the carbon nanotube 104 by metal-organic chemical vapor deposition (MOCVD) techniques, for example. Then, a material for use as the gate electrode 108 made of nickel silicide for example is deposited on the gate insulator film 106 by sputtering methods, for example. Thereafter, known lithography and reactive ion etch (RIE) techniques are used to pattern the gate electrode 108 and the gate insulator film 106. Thereafter, a silicon nitride film, for example, is deposited by low-pressure CVD (LPCVD) techniques, for example, followed by execution of etching by RIE to thereby form a sidewall dielectric film 110 on laterally opposite side surfaces of the gate electrode 108.

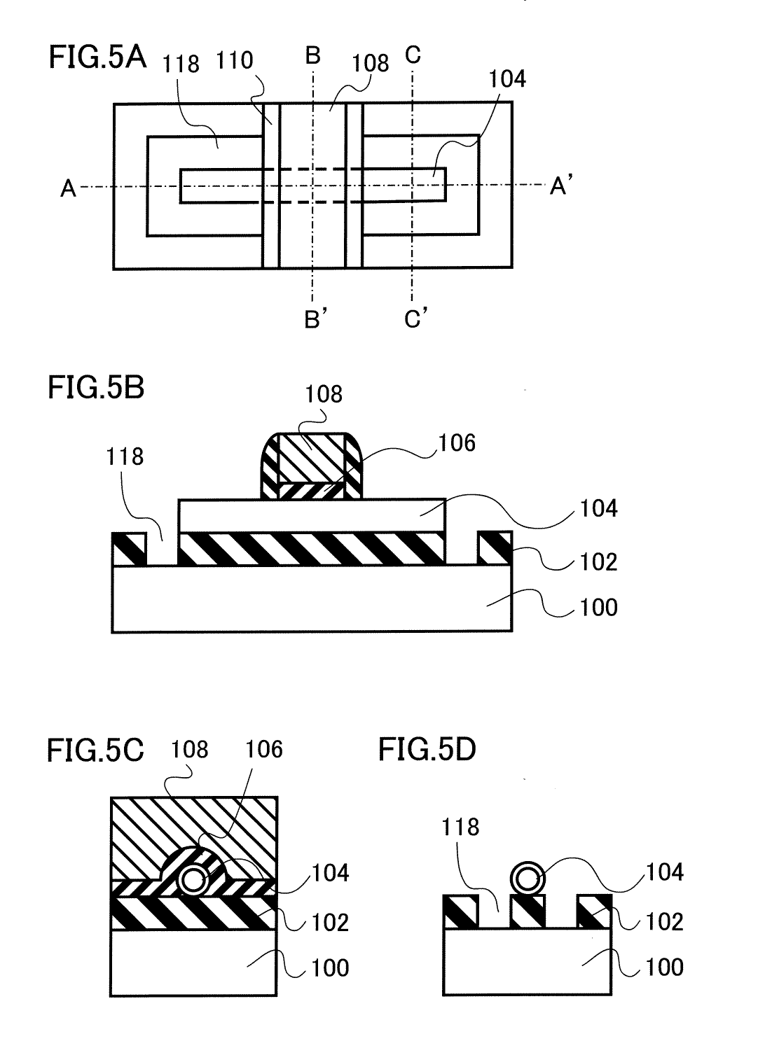

Next, as shown in a plan view of FIG. 5A, FIG. 5B which is a sectional view as taken along line A-A′ of FIG. 5A, FIG. 5C which is a sectional view taken along line B-B′ of FIG. 5A, and FIG. 5D that is a sectional view along line C-C′ of FIG. 5A, lithography and RIE methods are used to etch the dielectric film 102 with the gate electrode 108, the sidewall insulator film 110 and the carbon nanotube 104 being used as a mask. In this way, an opening part 118 is formed, at which the semiconductor substrate 100 is exposed.

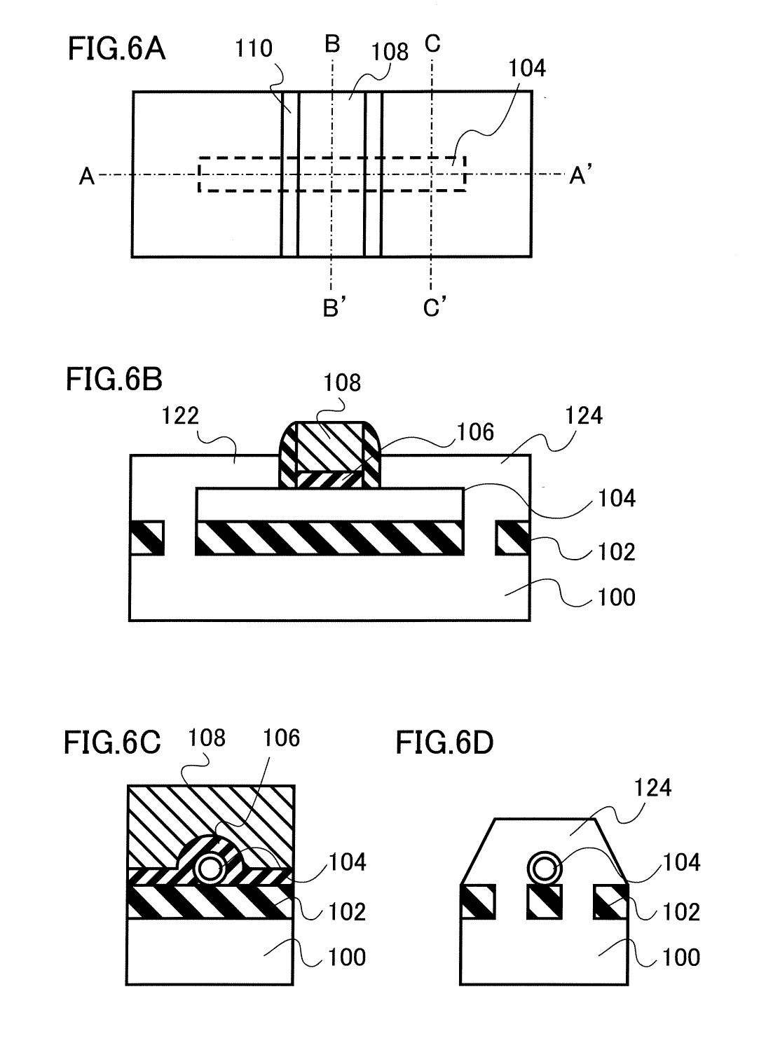

Next, as shown in a plan view of FIG. 6A, FIG. 6B which is a sectional view as taken along line A-A′ of FIG. 6A, FIG. 6C which is a sectional view taken along-line B-B′ of FIG. 6A, and FIG. 6D that is a sectional view along line C-C′ of FIG. 6A, a single-crystalline silicon that is the same material as the semiconductor substrate, for example, is formed by known epitaxial growth as semiconductor layers 122 and 124 on the semiconductor substrate 100 which was exposed at the opening 118. Here, the semiconductor layers 122 and 124 are for later use as parts of the source and drain regions, respectively. And, the semiconductor layer 122 and 124 are brought into contact in such a manner that these wrap the carbon nanotube 104 on both sides of the sidewall insulator film 110. Note here that the term “contact” refers to physical contact of the layers with each other, which leads to electrical conduction established therebetween.

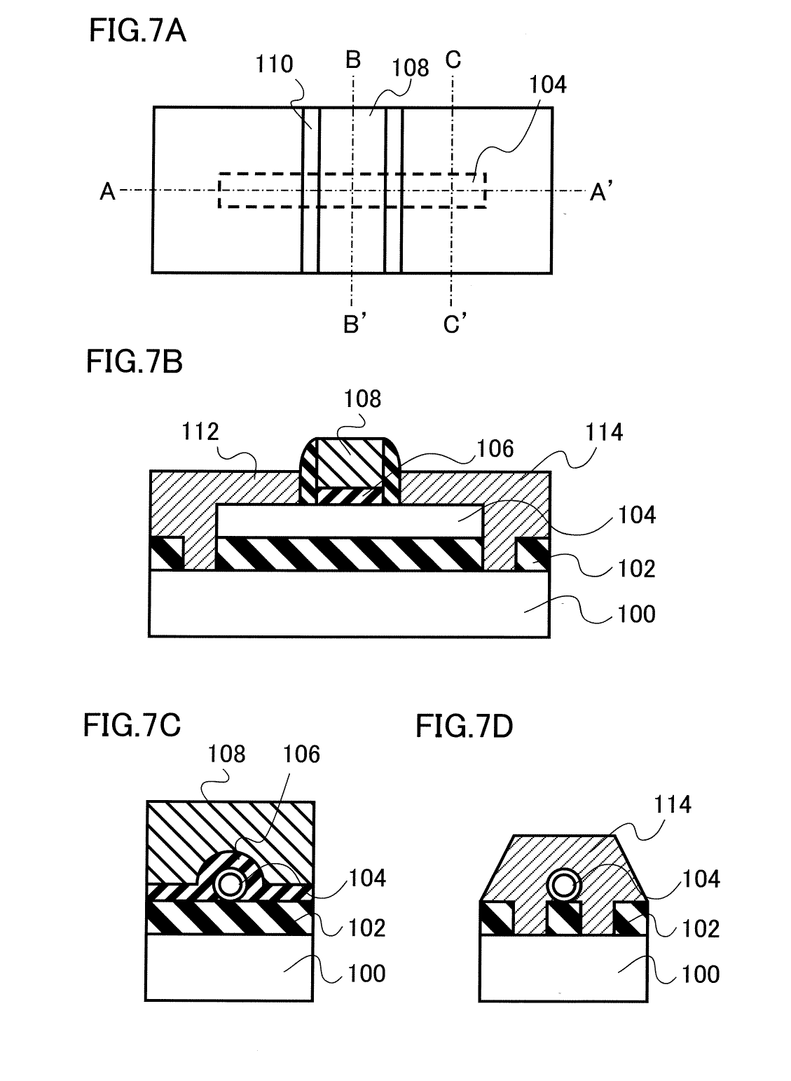

Next, as shown in a plan view of FIG. 7A, FIG. 7B which is a sectional view as taken along line A-A′ of FIG. 7A, FIG. 7C which is a sectional view taken along line B-B′ of FIG. 7A, and FIG. 7D that is a sectional view along line C-C′ of FIG. 7A, a chosen impurity such as arsenic (As) for example is introduced by ion implantation as an example into the semiconductor layers 122 and 124 to thereby form a pair of source region 112 and drain region 114 of the n-type conductivity.

Although one specific method was discussed here which uses the ion implantation process to alter the semiconductor layers 122 and 124 to the source region 112 and drain region 114, another process may alternatively be employable, which introduces an appropriate kind of impurity during epitaxial growth of the semiconductor layers 122 and 124 to thereby form the intended the n-type source and drain regions 112 and 114.

With the fabrication method of the semiconductor device of this embodiment, it becomes possible to readily manufacture the carbon nanotube transistor capable of suppressing drain leakage current and also increasing the turn-on current thereof.

### Second Embodiment

A semiconductor device in accordance with a second embodiment of this invention is similar principally to the first embodiment except that the semiconductor material of the portions of the source and drain regions which are in contact with the channel region is either polycrystalline or amorphous, so a duplicated explanation of it is eliminated herein for brevity purposes.

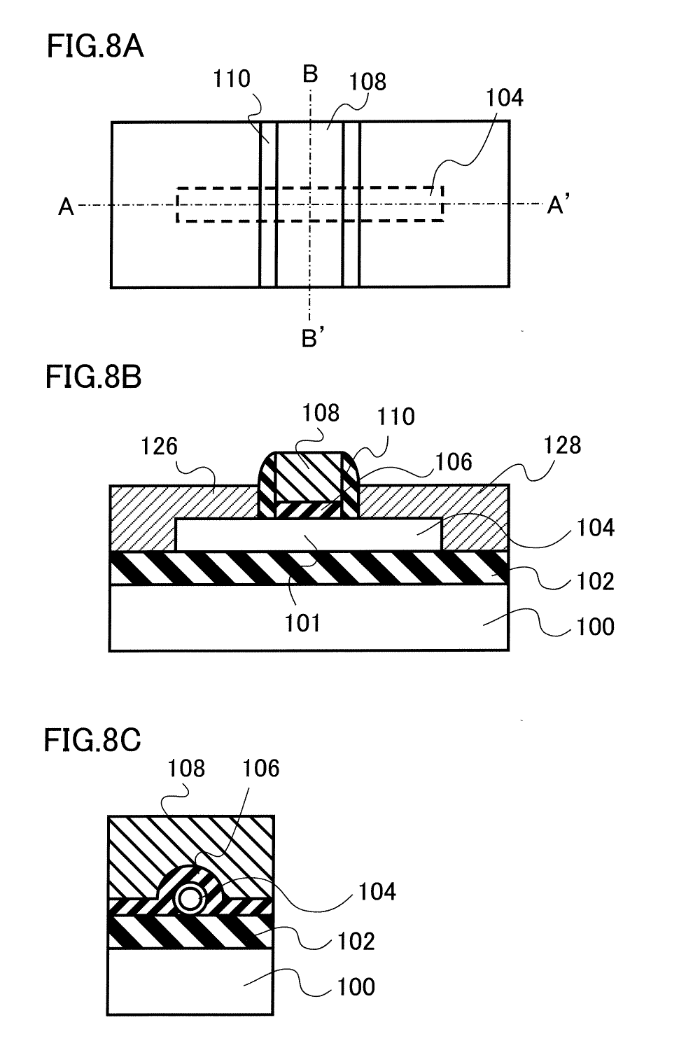

FIGS. 8A to 8C are diagrams illustrating an elemental structure of the semiconductor device of this embodiment. More precisely, FIG. 8A is a plan view, FIG. 8B is a sectional view as taken along line A-A′ of FIG. 8A, and FIG. 8C is a sectional view along line B-B′ of FIG. 8A.

As shown in FIG. 8B, the semiconductor device of this embodiment is arranged so that its channel region 101 is formed laterally between a pair of source region 126 and drain region 128, which are made of poly-silicon or amorphous silicon doped with an impurity such as arsenic (As) to have the n-type conductivity.

The single-crystal semiconductor source/drain region used in the first embodiment is a desirable material in view of the fact that the band gap unique to such material is stably realizable. In contrast, the polycrystalline or amorphous silicon film is fabricatable without requiring the to use of a seed crystal, unlike the single-crystal. Therefore, the semiconductor device of this embodiment has an advantage as to its ability to form the intended device structure while reducing process complexities, when compared to the case where the source and drain regions are made of monocrystalline semiconductor material. Another advantage lies in that the resulting structure formed by the fabrication method has substantially no contact between the semiconductor substrate and the source/drain region, which leads to a decrease in junction capacitance relative to the substrate. This contributes to enhancement of the speed performance of the carbon nanotube transistor.

### Third Embodiment

A semiconductor device of a third embodiment of this invention is similar to the first embodiment except that the semiconductor material of the portions of source and drain regions in contact with the channel region is silicon carbide (SiC), so its duplicated description is eliminated herein.

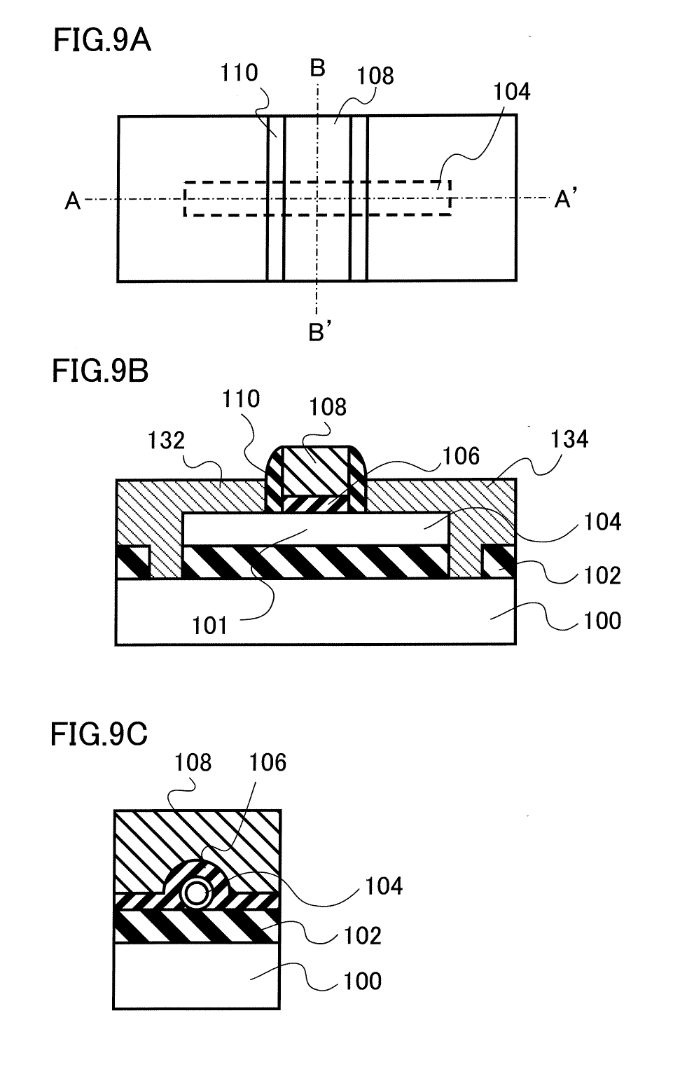

FIGS. 9A to 9C are diagrams depicting an element structure of the semiconductor device of this embodiment. FIG. 9A is a plan view, FIG. 9B is a sectional view as taken along line A-A′ of FIG. 9A, and FIG. 9C is a sectional view along line B-B′ of FIG. 9A.

As shown in FIG. 9B, the semiconductor device of this embodiment is such that a source region 132 and a drain region 134 which are made of silicon carbide that is doped with an impurity, such as arsenide (As), to have the n-type conductivity are formed so that a channel region 101 is laterally interposed between these source and drain regions. The silicon carbide has its energy band gap of from 2.36 eV to 3.33 eV, which is two or three times wider than that of the silicon. Therefore, according to this embodiment, it becomes possible to further suppress the drain leakage current otherwise flowing due to the tunneling of carbon nanotube.

It should be noted that the silicon carbide-made source and drain regions 132 and 134 are formable by epitaxial growth of the silicon carbide, in place of the epitaxial growth of silicon in the first embodiment as has been stated with reference to FIGS. 6A-6C. Alternatively, it is also considered that the source and drain regions may be formed by a process having the steps of doping or implanting carbon (C) ions into an epitaxially grown silicon and, thereafter, applying thermal processing thereto.

### Fourth Embodiment

A semiconductor device of fourth embodiment of this invention is similar to the first embodiment except that the portions of the source and drain regions in contact with the channel region are also provided at a cross-section part of the carbon nanotube, with a metal being filled in selected part on the source/drain region side of the carbon nanotube; so, its duplicated description is eliminated herein.

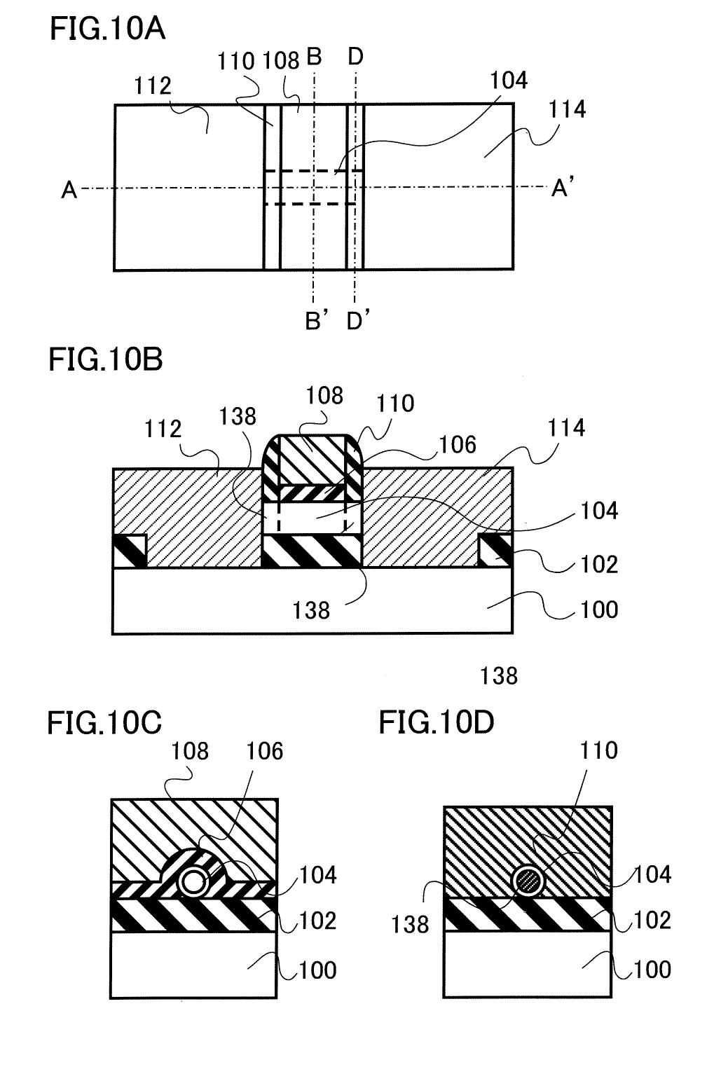

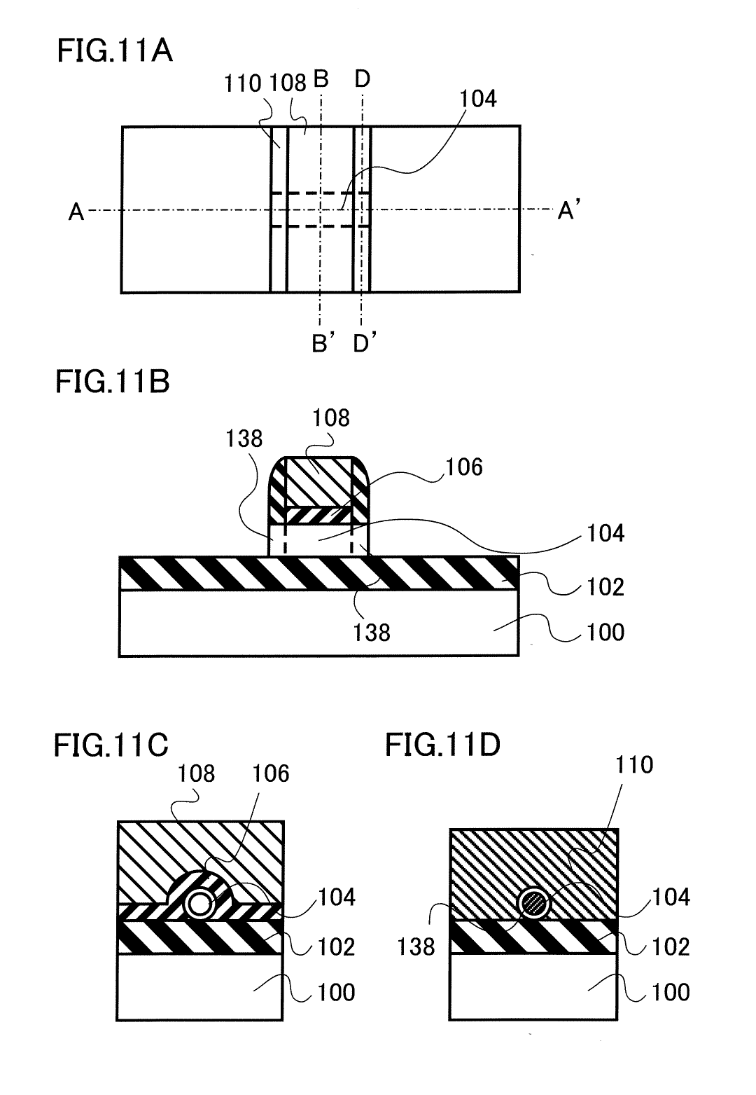

FIGS. 10A to 10C are diagrams showing an elementary structure of the semiconductor device of this embodiment. More specifically, FIG. 10A is a plan view, FIG. 10B is a sectional view as taken along line A-A′ of FIG. 11A, FIG. 10C is a sectional view taken along line B-B′ of FIG. 10A, and FIG. 10D is a sectional view along line D-D′ of FIG. 10A.

As shown in FIG. 10B, the semiconductor device of this embodiment has a source region 112 and drain region 114, which are made of single-crystalline silicon that is doped with an impurity, such as arsenide (As) for example, to have the n-type conductivity. These source and drain regions 112 and 114 are in contact or junction at cross-section part of a carbon nanotube 104 which forms the channel region of to transistor. Further, as shown in FIGS. 10B and 10D, a metal 138, such as kalium (K) as an example, is filled in internal part of the carbon nanotube 104 at such junction part—in other words, within the carbon nanotube 104 at its portions on the source and drain region sides, i.e., portions adjacent to the source region 112 and drain region 114. Note here that although in FIGS. 10A-10D one specific state with the metal 138 being filled at the junction part nearby portions only, the metal 138 may alternatively be internally filled to cover an entirety of the carbon nanotube, when the need arises.

According to this embodiment, by filling a metal in the inside portions of the carbon nanotube in contact with the source and drain regions, it becomes possible to appropriately adjust the electrical conduction characteristics and physical properties of the carbon nanotube. Thus it is possible to provide a carbon nanotube transistor capable of offering desired characteristics adjustability while at the same time suppressing or minimizing the flow of a tunnel current of the carbon nanotube. Note that the term characteristics in this case may refer to cutback of parasitic resistance due to contact resistance reduction, turn-on current increase due to improvement of the state density at the junction part, and/or enhancement of thermal durability.

Also note that preferable examples of the metal that is filled in the carbon nanotube are alkali metals, including but not limited to the kalium (K) stated above. Other examples of it are transition metals, such as iron (Fe) or else.

Next, an explanation will be given of a fabrication method of the semiconductor device of this embodiment shown in FIGS. 10A-10D while referring to FIGS. 11A to 13D. Note here that the procedure up to the process for formation of the sidewall insulator film shown in FIGS. 4A-4D is the same as that of the first embodiment, so its description is eliminated herein.

As shown in a plan view of FIG. 11A, FIG. 11B which is a sectional view as taken along line A-A′ of FIG. 11A, FIG. 11C is which is a sectional view taken along line B-B′ of FIG. 11A, and FIG. 11D that is a sectional view along line D-D′ of FIG. 11A, after having processed the sidewall insulator film 110, a carbon nanotube 104 is etched by use of RIE techniques, for example, with a gate electrode 108 and the sidewall insulator film 110 being used as a mask. Thereafter, a metal 138 which is comprised of kalium (K) as an example is internally filled in the carbon nanotube 104 from a cross-section part of carbon nanotube 104, for example.

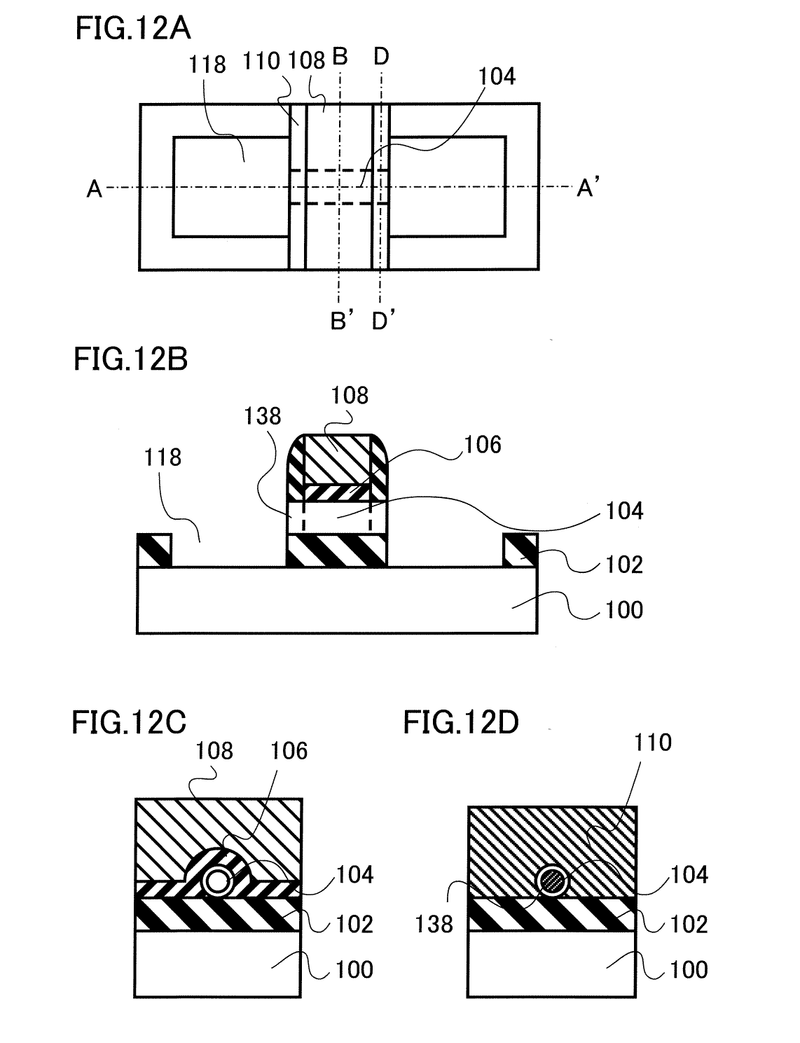

Next, as shown in a plan view of FIG. 12A, FIG. 12B which is a sectional view as taken along line A-A′ of FIG. 12A, FIG. 12C which is a sectional view taken along line B-B′ of FIG. 12A, and FIG. 12D that is a sectional view along line D-D′ of FIG. 12A, lithography and RIE techniques are used to etch a dielectric film 102 with the gate electrode 108 and sidewall insulator film 110 being used as a mask. In this way, an opening 118 is defined, at which the semiconductor substrate 100 is partly exposed.

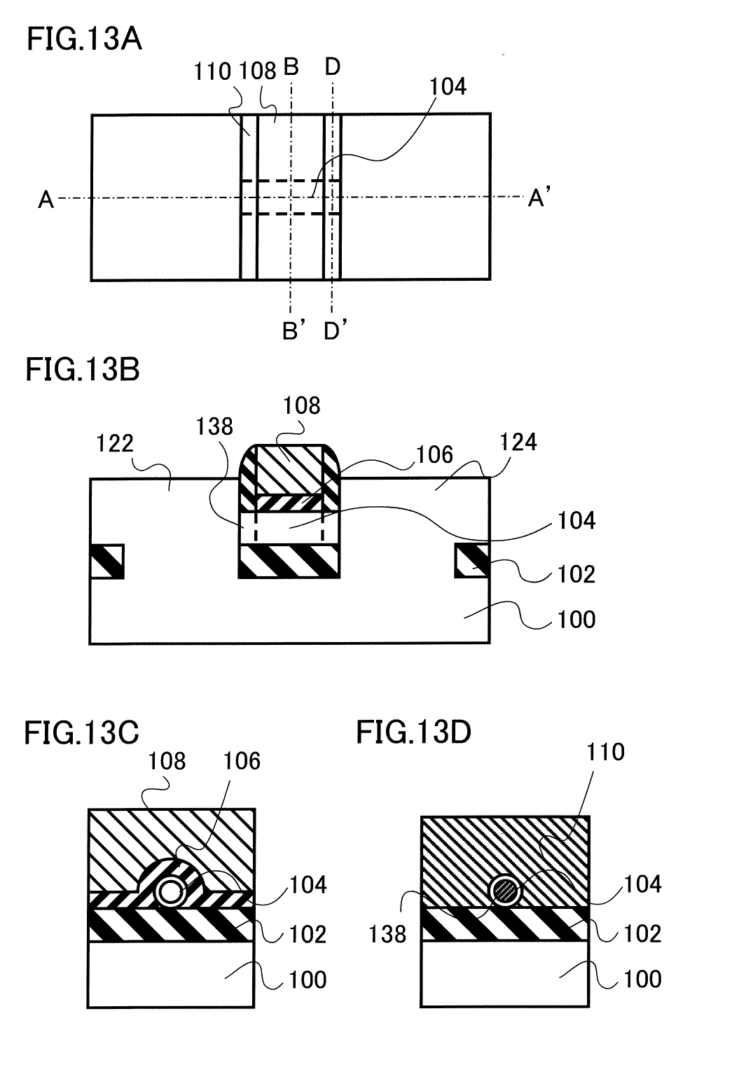

Next, as shown in a plan view of FIG. 13A, FIG. 13B which is a sectional view as taken along line A-A′ of FIG. 13A, FIG. 13C which is a sectional view taken along line B-B′ of FIG. 13A, and FIG. 13D that is a sectional view along line D-D′ of FIG. 13A, known epitaxial growth technique is used to form, as semiconductor layers 122 and 124, a single-crystal silicon body that is the same material as the semiconductor substrate, for example, on the semiconductor substrate 100 which was exposed at the opening 118. Here, the semiconductor layers 122 and 124 will later become portions of the source and drain regions, respectively. And, these semiconductor layers 122 and 124 are forced to come into contact with the cross-section part of the carbon nanotube 104 on both sides of the sidewall dielectric film 110. Thereafter, an impurity of arsenic (As) as an example is doped by ion implantation into the semiconductor layers 122 and 124 to thereby form n-type source and drain regions 112 and 114 as shown in FIGS. 10A -10D.

With the fabrication method of the semiconductor device of this embodiment, it is possible to readily manufacture a carbon nanotube transistor capable of suppressing drain leakage current and also increasing its turn-on current while simultaneously offering an ability to adjust to any desired characteristics.

Additionally, although in this embodiment one specific form for filling a metal in the carbon nanotube has been explained, the above-stated device structure and fabrication method may alternatively be applicable to other possible forms of the invention having no such metal fulfillment feature.

### Fifth Embodiment

A semiconductor device of fifth embodiment of this invention is basically similar to the first embodiment except that the semiconductor material of the portions of source and drain regions in contact with the channel region is formed of a carbon nanotube which is smaller in diameter than the carbon nanotube of the channel region; so, its duplicated description is omitted herein.

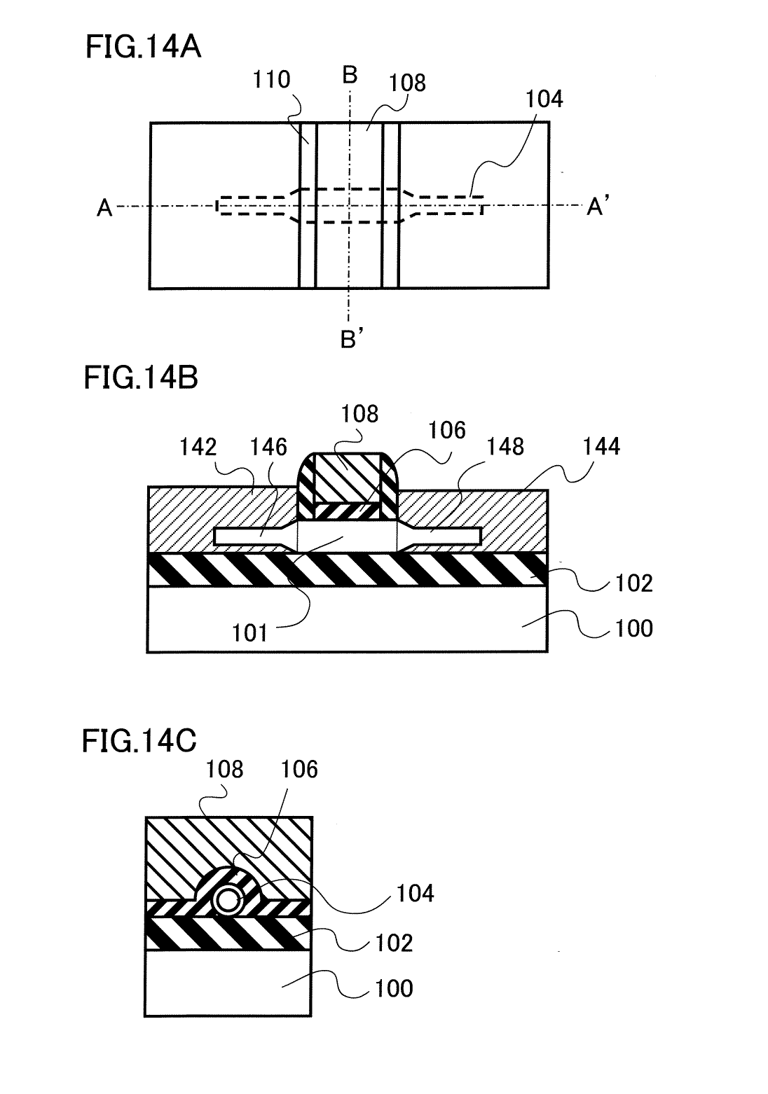

FIGS. 14A to 14C are diagrams showing a structure of the semiconductor device of this embodiment. Specifically, FIG. 14A is a plan view, FIG. 14B is a sectional view as taken along line A-A′ of FIG. 14A, and FIG. 14C is a sectional view taken along line B-B′ of FIG. 14A.

As shown in FIG. 14B, the semiconductor device of this embodiment is designed so that its source region is formed of a carbon nanotube 146 and a source electrode 142 whereas a drain region is made up of a carbon nanotube 148 and a drain electrode 144. The carbon nanotube 146 of the source region and the carbon nanotube 148 of the drain region are doped with an alkali metal, such as for example kalium (K) or a transition metal such as Fe or the like, to have the n-type conductivity. Accordingly, a p-n junction is created between the carbon nanotube of channel region 101 and the carbon nanotube 146 of the source region on one hand and the carbon nanotube 148 of the drain region on the other hand.

Here, for example, the carbon nanotube of the channel region 101 has its diameter of about 1.5 nm whereas the carbon nanotubes of the source and drain regions have a diameter of about 1.0 nm. The source electrode 142 and the drain electrode 144 are each made of palladium (Pd), for example. The carbon nanotube diameter values and the source/drain electrode material may arbitrarily be selectable on a case-by-case basis.

As previously stated, the band gap of the carbon nanotube is variable depending on the diameter of carbon nanotube: the band gap tends to expand with a decrease in diameter. Consequently, according to this embodiment with the carbon nanotubes of the source and drain regions at the portions in contact with the channel region being less in diameter than the carbon nanotube of the channel region, it becomes possible to suppress the carbon nanotube's tunnel current more successfully when compared to a case where the diameters are equal in value.

The semiconductor device of this embodiment is manufacturable by using, during carbon nanotube formation, a method as will be described below. First, a carbon nanotube created is subjected to cutting. An exemplary method of this cutting includes the steps of making defects through exposure to a high-temperature fluorine gas and then removing the fluorine by hydrazine (H₂NNH₂). By oxidizing here the defects by a mixture of sulfuric acid plus hydrogen peroxide solution, the carbon nanotube is cut. In this way, is it is possible to obtain a short carbon nanotube which is opened by addition of a functional group (—CO₂H) to an end. Next, metallic micro-particles for use as a catalytic agent are added to both ends of the carbon nanotube which was cut. An example of the process of attaining this is as follows: FeO micro-particles are forced to be weakly coupled to the functional group at the both ends of the carbon nanotube by fusion into a [Fe(NO₃)₃]-containing solvent and then evaporation of this solvent. Then, the carbon nanotube with weak coupling of the FeO microparticles is applied thermal processing in a hydrogen atmosphere, thereby enabling addition of Fe microparticles to both ends of the carbon nanotube.

Thereafter, by known CVD technique as an example, the carbon nanotube is caused to further grow from the Fe microparticles acting as the catalyzer at the both ends of the carbon nanotube in the way stated supra. The diameter of the carbon nanotube to be grown here is controllable by adjustment of the size of catalyst particles and the pressure and temperature of the atmosphere gas used. For example, the size of Fe microparticles for use as the catalyzer is adjustable by the concentration of [Fe(NO₃)₃].

After having formed the carbon nanotube thus formed in this way on a dielectric layer on a semiconductor substrate in a similar way to the process of the fabrication method of the first embodiment shown in FIGS. 3A-3D, the semiconductor device of this embodiment is manufacturable by a similar method to the fabrication method of the first embodiment. It is noted that in the case of a metal being formed at the source and drain electrodes as stated previously, the silicon epitaxial growth in the first embodiment may be changed to known metal electrode forming methods.

Additionally, when fabricating the semiconductor device of this embodiment, it is also possible to manufacture the carbon nanotubes of the source and drain regions which are less in diameter than the channel region in such a manner as to be self-aligned with the gate electrode.

More specifically, as has been stated in the explanation of the fourth embodiment with reference to FIGS. 11A-11D, the carbon nanotube 104 is etched with the gate electrode 108 and sidewall insulator film 110 as a mask after having processed the sidewall insulator film 110.

Thereafter, Fe microparticles are added by the above-stated method to the both ends of the carbon nanotube 104 thus exposed. Then, by known CVD technique, a narrow or “slender” carbon nanotube which is less in diameter than the carbon nanotube of the channel region is grown from the Fe microparticles for use as the catalyzer at both ends of the carbon nanotube while controlling growth conditions thereof.

Thereafter, through processes similar to the fabrication steps which have been explained by using FIGS. 5A to 7D in conjunction with the fabrication method of the first embodiment as an example, it is possible to manufacture the semiconductor device of this embodiment in the self-aligned manner. Here, in case a metal is formed at the source and drain electrodes, the silicon epitaxial growth in the first embodiment may be replaced by known metal electrode formation methods as in the aforementioned fabrication method of this embodiment.

### Sixth Embodiment

A semiconductor device of sixth embodiment of this invention is basically similar to the first and fifth embodiments except that the semiconductor material of the portions of source and drain regions in contact with the channel region is boron nitride nanotube (BNNT) so that its duplicated description is eliminated herein.

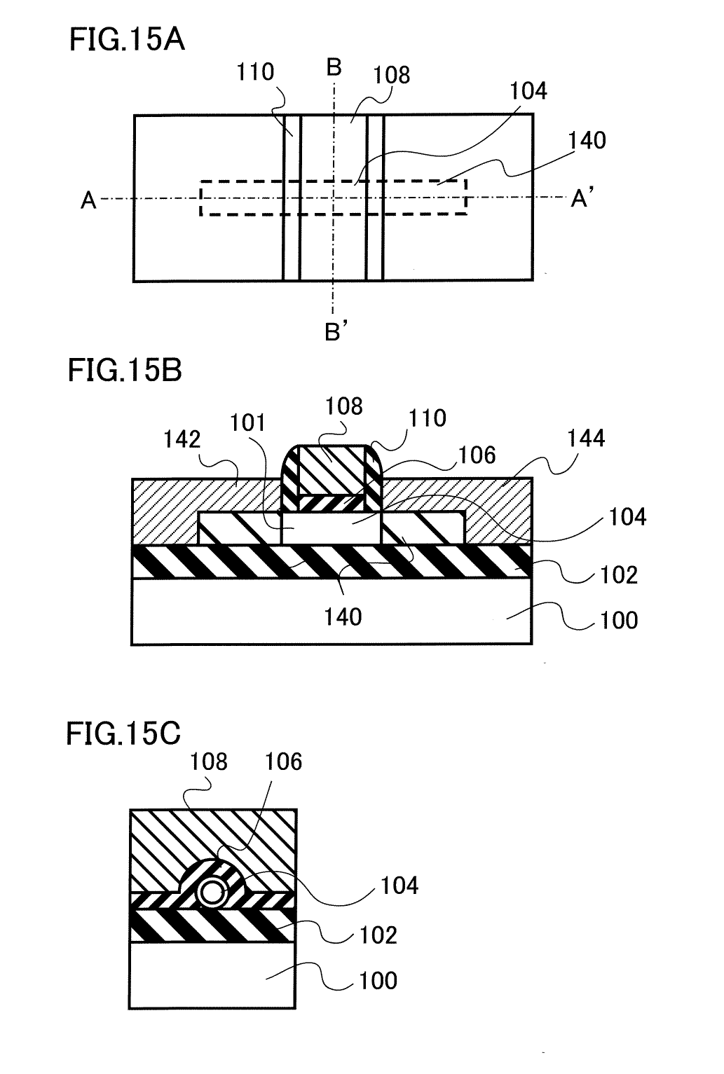

FIGS. 15A to 15C are diagrams showing the structure of is the semiconductor device of this embodiment. Specifically, FIG. 15A is a plan view, FIG. 15B is a sectional view as taken along line A-A′ of FIG. 15A, and FIG. 15C is a sectional view taken along line B-B′ of FIG. 15A.

As shown in FIG. 15B, the semiconductor device of this embodiment is such that its source region is structured from a boron nitride nanotube 140 and a source electrode 142 whereas a drain region is formed of a boron nitride nanotube 140 and a drain electrode 144. Here, the boron nitride nanotube 140 is made for example of an alkali metal such as kalium or a transition metal such as Fe or the like, which is doped with a chosen impurity to have the n-type conductivity. The source and drain electrodes 142 and 144 are made of palladium (Pd) as an example.

The boron nitride nanotube has its band gap of 6.1 eV, which is about six times greater than that of the silicon. Thus, according to this embodiment, it becomes possible to further suppress the drain leakage current that is derived due to the tunneling of the carbon nanotube.

It is noted that the boron nitride nanotube 140 is formable by a process having the steps of forming the sidewall dielectric film 110 which has been explained in the first embodiment with reference to FIGS. 4A-4D and changing the exposed part of the carbon nanotube 104 to a boron nitride nanotube with the gate electrode 108 and sidewall insulator film 110 being used as a mask. More specifically, thermal processing is applied to the exposed carbon nanotube 104 in a B₂O₂/N₂ gas atmosphere, causing B₂O₂ and N₂ gases to react with the carbon nanotube to thereby substitute it to the boron nitride nanotube.

Here, the band gap of the boron nitride nanotube is dependent upon its diameter: the less the diameter value, the narrower the band gap. Thus it is possible by adjusting the boron nitride nanotube diameter to provide the intended carbon nanotube transistor with optimum characteristics, e.g., excellent drain leakage characteristics and turn-on current property.

Additionally, by the process of forming a carbon nanotube with the source and drain regions being different in diameter from the channel region and then changing its source and drain regions to a boron nitride nanotube as indicated for example in the fabrication method of the fifth embodiment, it becomes possible to achieve optimization of the characteristics of the carbon nanotube transistor.

### Seventh Embodiment

A semiconductor device of seventh embodiment of this invention is principally similar to the first embodiment except that its source and drain regions are made of an impurity-segregated semiconductor layer and metal silicide, so its duplicated description is omitted herein.

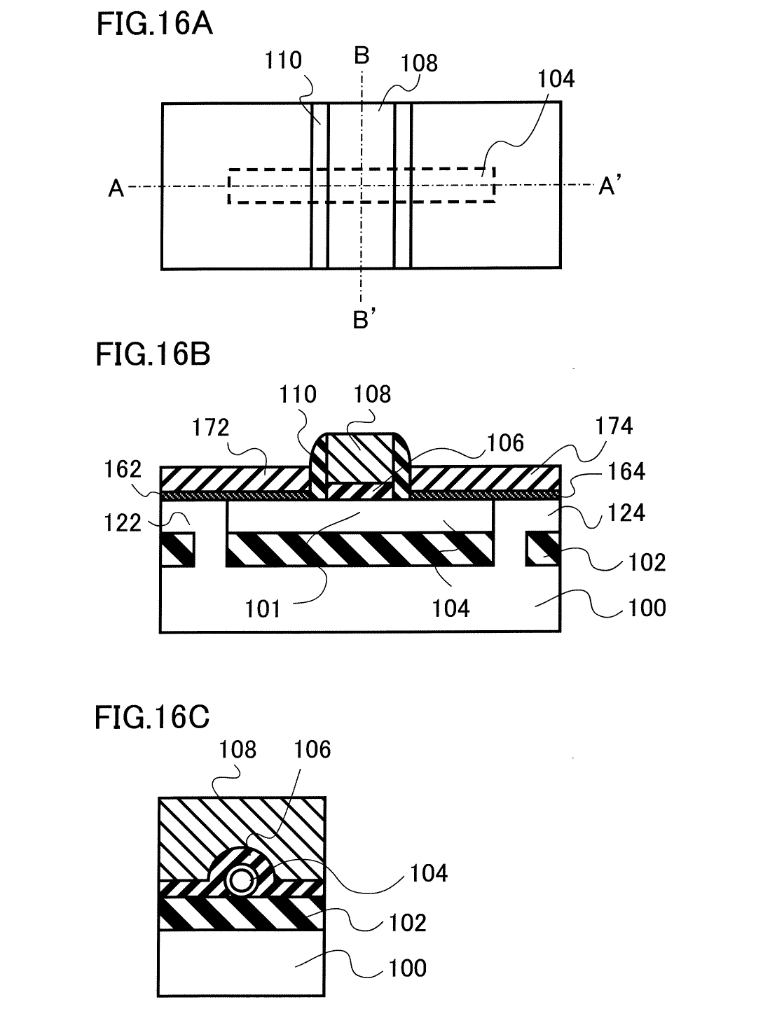

FIGS. 16A to 16C are diagrams showing the structure of the semiconductor device of this embodiment. Specifically, FIG. 16A is a plan view, FIG. 16B is a sectional view as taken along line A-A′ of FIG. 16A, and FIG. 16C is a sectional view taken along line B-B′ of FIG. 16A.

As shown in FIG. 16B, the semiconductor device of this embodiment is arranged so that the source and drain regions are each formed of an impurity-segregated semiconductor layer 162, 164 and a metal silicide layer 172, 174. In other words, this embodiment device is a carbon nanotube transistor which is equivalent in structure and function to what is called the impurity segregation Schottky transistor.

Note here that the impurity-segregated semiconductor layer 162, 164 refers to a thin impurity layer with a chosen impurity, e.g., arsenic (As), being heavily doped thereinto to an increased level of concentration. This impurity-segregated semiconductor layer has an n-type impurity concentration at an interface with the metal silicide layer 172, 174, which concentration falls within a range of from about 8×10¹⁹ atoms/cm³ to about 5×10²⁰ atoms/cm³. An n-type impurity concentration of this layer at a depth of 20 nm from the interface is less than or equal to one-tenth ( 1/10) of the n-type impurity concentration at the interface.

The impurity segregation Schottky transistor has such thickness-reduced high-concentration impurity segregated semiconductor layer at an electrode interface of the metal silicide layer whereby the effective Schottky barrier height is lowered, causing the electrode's parasitic resistance to decrease accordingly. Consequently, according to this embodiment, it becomes possible to achieve a high-performance carbon nanotube transistor with an increased turn-on current while at the same time suppressing the drain leakage current of the carbon nanotube transistor.

Additionally, the reason of defining the impurity distribution of the impurity-segregated semiconductor layer 162, 164 in the way stated above is that a decrease in the effective Schottky barrier height is not sufficiently expectable if the value becomes less than the above-noted impurity concentration range of the interface. Conversely, if the depth at which the impurity concentration at the interface is equal to or less than 1/10 becomes greater than 20 nm, the resulting characteristics can be deteriorated due to the presence of the parasitic resistance of the impurity-segregated semiconductor layer per se and also due to the occurrence of short-channel effects.

The semiconductor device of this embodiment is fabricatable in a way which follows. Firstly, after having formed by known epitaxial growth a layer of monocrystalline silicon that is the same material as the semiconductor substrate for use as semiconductor layers 122 and 124 in the way which has been discussed in the first embodiment with reference to FIGS. 6A-6D, a chosen impurity, e.g., arsenic (As), is introduced by ion implantation into the semiconductor layers 122 and 124. Process conditions at this time are set to ensure that a p-n junction is created at a position which is shallower than the film thickness of metal silicide layers 172 and 174 which are made for example of nickel silicide (NiSi) to be later formed. Then, known metal silicide formation technique is used to form the metal silicide layers 172 and 174. In doing so, the impurity, e.g., arsenic (As), behaves to segregate at the interface of metal silicide by silicidation of the metal, resulting in formation of the impurity-segregated semiconductor layers 162 and 164.

Several illustrative embodiments of this invention have been described while referring to practical examples thereof. The above-noted embodiments are indicated merely as examples and are not the ones that limit the invention. Additionally, although in the description of the embodiments an explanation is omitted as to those parts or components which are not directly needed for the description of this invention in the semiconductor devices and semiconductor device fabrication methods and others, any required elements concerning a semiconductor device and a semiconductor device fabrication method may be arbitrarily selected and used on a case-by-case basis.

In the embodiments as disclosed herein, n-type field effect transistors have been chiefly explained as examples; however, regarding p-type field effect transistors also, similar functions and effects to the n-type field effect transistors are obtainable—a difference therebetween is that the carriers are changed from electrons to holes. As for the carbon nanotube, any one of a single-layered carbon nanotube and a multilayered carbon nanotube is employable.

Miscellaneously, all semiconductor devices and semiconductor device fabrication methods which comprise the subject matter of this invention and which are arbitrarily changed in design by the person skilled in the art are encompassed within the scope of the invention. The invention is, therefore, to be limited only as indicated by the scope of the appended claims and equivalents thereto.

What is claimed is:

1. A semiconductor device comprising:
a channel region formed of a carbon nanotube (CNT);
a gate dielectric film on the channel region;
a gate electrode on the gate dielectric film; and
a pair of source and drain regions interposing the channel region therebetween, wherein
portions of the source and drain regions in contact with the channel region are made of a semiconductive material which is wider in band gap than the channel region.

2. The device according to claim 1, wherein the semiconductive material is higher in state density than the carbon nanotube.

3. The device according to claim 1, wherein the semiconductive material is silicon (Si).

4. The device according to claim 1, wherein the semiconductive material is silicon carbide (SiC).

5. The device according to claim 1, wherein the semiconductive material is a boron nitride nanotube (BNNT).

6. The device according to claim 1, wherein the semiconductive material is a carbon nanotube which is less in diameter than the carbon nanotube forming the channel region.

7. The device according to claim 1, wherein the source and drain regions are each comprised of an impurity-segregated semiconductor layer and a metal silicide.

8. The device according to claim 1, wherein the semiconductive material is a single-crystal.

9. The device according to claim 1, wherein the carbon nanotube forming the channel region has metal-filled portions located adjacent to the source and drain regions.

10. The device according to claim 9, wherein the metal-filled portions contain therein an alkali metal.

11. A method of manufacturing a semiconductor device, comprising:
forming a dielectric layer on a semiconductor substrate;
forming on the dielectric layer a carbon nanotube for use as a channel region;
forming a gate insulation film on the carbon nanotube;
forming a gate electrode on the gate insulation film;
forming a sidewall insulator film on laterally opposite sides of the gate electrode;
etching the dielectric layer with the gate electrode and the sidewall insulator film being used as a mask to thereby partially expose the semiconductor substrate; and
forming by epitaxial growth a semiconductor layer on the semiconductor substrate to thereby cause the semiconductor layer to come into contact with the carbon nanotube, the semiconductor layer becoming part of a source region and a drain region.

12. The method according to claim 11, wherein the semiconductor layer is a silicon layer.

13. The method according to claim 11, wherein the semiconductor layer is a silicon carbide layer.

14. The method according to claim 11, further comprising:
prior to the etching of the dielectric layer, etching the carbon nanotube with the gate electrode and the sidewall insulator film being used as a mask.

15. The method according to claim 14, further comprising:
after having etched the carbon nanotube, filling a metal in the carbon nanotube.

16. A method of manufacturing a semiconductor device, comprising:
forming a dielectric layer on a semiconductor substrate;
forming on the dielectric layer a carbon nanotube for use as a channel region;
forming a gate insulation film on the carbon nanotube;
forming a gate electrode on the gate insulation film;
forming a sidewall insulator film on both sides of the gate electrode; and
changing by substitution the carbon nanotube to a boron nitride nanotube with the gate electrode and the sidewall insulator film being used as a mask.

17. The method according to claim 16, wherein the substitution to the boron nitride nanotube is performed by causing the carbon nanotube to react with boric oxide (B₂O₂) and nitrogen (N₂) gases.
